(19) United States
(12) Patent Application Publication
(10) Pub. No.: US 2009/0250801 A1
(43) Pub. Date: Oct. 8, 2009

(54) Semiconductor device

(75) Inventors: Satoshi Isa, Tokyo (JP); Mitsuaki Katagiri, Tokyo (JP); Dai Sasaki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/385,138

(22) Filed: Mar. 31, 2009

(30) Foreign Application Priority Data
Apr. 3, 2008 (JP) 2008-097271

(51) Int. Cl. H01L 25/16

(52) U.S. Cl. 257/686; 257/E25.03

(57) ABSTRACT

A semiconductor device in which a plurality of semiconductor elements are stacked, yet realizing high speed operation of the semiconductor elements. The semiconductor device is provided with semiconductor packages, and a spacer. The semiconductor packages are stacked, with the spacer interposed therebetween. The semiconductor packages have, respectively, package boards, and semiconductor elements mounted on the package boards. The spacer has a plurality of conductive vias and a capacitor element. The semiconductor packages are electrically connected through the conductive vias. The capacitor element is electrically connected, among the conductive vias, to a conductive via that electrically connects the semiconductor element and power supply, and a conductive via that electrically connects the semiconductor element and ground.

### REFERENCE TO RELATED APPLICATION

This application is based upon and claims the benefit of the priority of Japanese patent application No. 2008-097271, filed on Apr. 3, 2008 the disclosure of which is incorporated herein in its entirety by reference thereto.

### BACKGROUND OF THE INVENTION

1. Field of the Invention

The present invention relates to a semiconductor device in which a plurality of semiconductor elements are stacked.

2. Description of Related Art

Along with increasing speed and increasing capacity of semiconductor elements in recent years, in order to have small sized electronic devices in which the elements are installed, packages thereof are increasingly being made smaller. For example, semiconductor memory elements such as Dynamic Random Access Memory (DRAM) are provided with gigabit range memory capacities, and with regard to packages thereof, small sized packages are being developed, such as a Ball Grid Array (BGA) type, of a surface-mount type in which solder balls are arrayed on a package board. The BGA is employed, for example, in general purpose DRAMs such as DDR2 (Double Data Rate 2) DRAM and the like.

In order to realize semiconductor memory devices having large capacities with small mounting areas, implementation configurations (Package on Package (PoP)) are being developed in which plural semiconductor packages of these types are stacked on a mounting board (for example, refer to Patent Document 1 and Patent Document 2).

A semiconductor device as described in Patent Document 1 has a plurality of wiring boards each of which is provided with a plurality of vias, in which connecting electrodes are formed, and with wiring that is electrically connected to the connecting electrodes, semiconductor elements which are mounted on the wiring boards and are electrically connected to the wiring, and chip cavity sections in which the semiconductor elements are contained when the semiconductor elements are mounted, and which have capacities larger than the semiconductor element capacities; the semiconductor device is also provided with a plurality of conductive via insulating boards provided with connecting electrodes formed so as to be buried in the plurality of via holes; a stacked body is formed in which one of the conductive via insulating boards and one of the wiring boards are stacked such that connection wiring of the conductive via insulating board in the wiring board and connection electrodes of the wiring board are electrically connected; and the stacked body has a plurality of layers and is integrated, in a state in which the semiconductor elements mounted on the wiring board are completely contained in the chip cavity section.

A semiconductor package as described in Patent Document 2 is a semiconductor package in which a routing IC, a flip chip IC, and/or a spacer are stacked in a three dimensional manner, and the routing IC is provided with a through-hole for connecting to an adjacent layer or a base board, an electrical means for mutually connecting both upper and lower surfaces of the routing IC, and at least one passive element.

With regard to a PoP, in cases in which there is a large number of power supply/GND lines and signal lines electrically connecting pads on a package board on which a semiconductor element is mounted, the diameter of solder balls electrically connecting between a package and a board has to be made small in order to prevent shorting between adjacent solder balls. As a result, there are cases in which it is not possible to secure sufficient space (in a direction of thickness) in order to mount the semiconductor element between package boards. Therefore, to secure space for mounting the semiconductor element between the package boards, in general the conductive via insulating board described in Patent Document 1 or the spacer described in Patent Document 2 are provided between the package boards.

FIG. 9 shows a schematic top plan view viewed from above a spacer, of a semiconductor device according to the background technology. FIG. 10 shows a schematic cross sectional view of the semiconductor device according to the background technology along a line X-X of FIG. 9. In FIG. 9, a second semiconductor package 53 above a spacer 801 shown in FIG. 10 is not illustrated.

The semiconductor device 51 has a mounting board 601, and a first semiconductor package 52 and the second semiconductor package 53 stacked on the mounting board 601. In the semiconductor packages 52 and 53, semiconductor elements 702 and 712 are mounted on package boards 701 and 711. Spacers 801 of a strip form are disposed on each side of the first semiconductor element 702, between the package boards 701 and 711. Pads 803 and conductive vias 804 are formed in the spacers 801, and the spacers 801 electrically connect the first semiconductor package 52 and the second semiconductor package 53, through conductive bodies 717 and 806. A capacitor element 602 is mounted on the mounting board 601, and is electrically connected to a power supply and ground.

### [Patent Document 1]

JP Patent Kokai Publication No. JP-P2001-68624A

### [Patent Document 2]

JP Patent Kokai Publication No. JP-P2003-60153A

### SUMMARY

The entire disclosures of above Patent Documents are incorporated herein by reference thereto.

The following analysis is given from a viewpoint of the present invention.

In a PoP type of semiconductor device such as described in Patent Document 1 and shown in FIG. 9 and FIG. 10, wiring length from a mounting board on which a package is mounted becomes longer, in going to a semiconductor package in a top stage. As a result, there is a problem in that impedance between the power supply and GND viewed from a semiconductor element, that is, a resistance component and an inductance component, increase, so that high speed operation of the semiconductor element is restricted.

In addition, in the semiconductor package described in Patent Document 2, a capacitor element is built into the routing IC, but with regard to a board with a capacitor element built-in, such as the routing IC described in Patent Document 2, a manufacturing process thereof becomes complicated, and special material or a special manufacturing process becomes necessary, so that cost inevitably increases. As a result, in cases of packages in which board area is large, the cost greatly increase. Moreover, in cases in which a semiconductor element that does not have a preferable electrical characteristic is mounted on the package board, the whole of the high-cost package board must be rejected, and the cost greatly increases. Therefore, in stacked packages of general-use DRAMs for which cost is viewed as being of primary importance, employing technology disclosed in Patent Document 2 is difficult.

The present invention seeks to solve one or more of the above problems, or to improve upon those problems at least in part.

According to a first aspect of the present invention, there is provided a semiconductor device in which plural semiconductor packages are stacked with an intervening spacer(s), the package comprising a semiconductor element mounted on a package board. A spacer has a plurality of conductive vias and at least one capacitor element. The plural semiconductor packages are electrically connected to one another by the conductive vias. The capacitor element is electrically connected, among the plurality of conductive vias, to a first conductive via that electrically connects the semiconductor element and a power supply, and to a second conductive via that electrically connects the semiconductor element and ground.

According to a preferred mode of the abovementioned first aspect, the spacer is a frame unit that has a through-hole section penetrating in a direction of stacking of the semiconductor packages. The semiconductor element, which is disposed between two of the semiconductor packages that are adjacently stacked, is inserted in the through-hole section of the spacer that is arranged between the two semiconductor packages.

According to a preferred mode of the abovementioned first aspect, the capacitor element is mounted on the spacer. The capacitor element and the first conductive via and the second conductive via are electrically connected by a wiring layer formed on the spacer.

According to a preferred mode of the abovementioned first aspect, the spacer has an electrical connection section in which the plurality of conductive vias are formed, and a capacitor element mounting section in which the capacitor element is mounted. A thickness of the capacitor element mounting section in a direction of stacking of the semiconductor packages is thinner than that of the electrical connection section.

According to a preferred mode of the abovementioned first aspect, the capacitor element is electrically connected to the conductive via by wire bonding.

According to a preferred mode of the abovementioned first aspect, the capacitor element is built in the spacer.

According to a preferred mode of the abovementioned first aspect, the spacer additionally has a dielectric and a plurality of conductor layers stacked in the dielectric. The plurality of conductor layers have a first conductor layer electrically connected to the first conductive via, and a second conductor layer electrically connected to the second conductive via. The capacitor element is formed by the first conductor layer and the second conductor layer being alternately stacked, with intervention the dielectric.

According to a preferred mode of the abovementioned first aspect, the first conductor layer and the second conductor layer are not electrically connected, among the plurality of conductive vias, to a third conductive via that is for a signal.

The present invention possesses at least one of the following effects.

According to the present invention, by providing the capacitor element in a spacer which electrically connects the semiconductor packages and secures a space for receiving the semiconductor element, it is possible to shorten the wiring length between the semiconductor element and the capacitor element as compared with the case of in a semiconductor device in which the capacitor element is installed on a mounting board on which the semiconductor packages are mounted. In this way, the resistance component and the inductance component with respect to high frequency viewed from the semiconductor element become small as compared to cases where the capacitor element is not installed on the spacer, and the impedance between the power supply and GND decreases, so that it is possible to realize high speed operation of the semiconductor element.

Moreover, according to the present invention, since the capacitor element is not mounted on/built in the package board of the semiconductor package, it is possible to curtail manufacturing cost of the semiconductor packages with the present invention, as compared to the case with semiconductor packages in which the capacitor element is mounted on/built in the package board. In this way, in cases where a semiconductor element that does not have an acceptable electrical characteristic is mounted on a semiconductor package, it is possible to reduce the cost incurred by rejecting the semiconductor package.

### BRIEF DESCRIPTION OF THE DRAWINGS

FIG. 1 shows a schematic top plan view viewed from above a spacer, in a semiconductor device according to a first exemplary embodiment.

FIG. 2 shows a schematic cross sectional view of the semiconductor device along a line II-II of FIG. 1.

FIG. 3 shows a schematic cross sectional view of the semiconductor device along a line III-III of FIG. 1.

FIG. 4 shows a schematic top plan view viewed from above a spacer, in a semiconductor device according to a second exemplary embodiment.

FIG. 5 shows a schematic cross sectional view of the semiconductor device along a line V-V of FIG. 4.

FIG. 6 shows a schematic top plan view viewed from above a spacer, in a semiconductor device according to a third exemplary embodiment.

FIG. 7 shows a schematic cross sectional view of the semiconductor device along a line VII-VII of FIG. 6.

FIG. 8 shows a schematic cross sectional view of the spacer of the semiconductor device along a line VIII-VIII of FIG. 6.

FIG. 9 shows a schematic top plan view viewed from above the spacer, in an example of a semiconductor device according to a background technology.

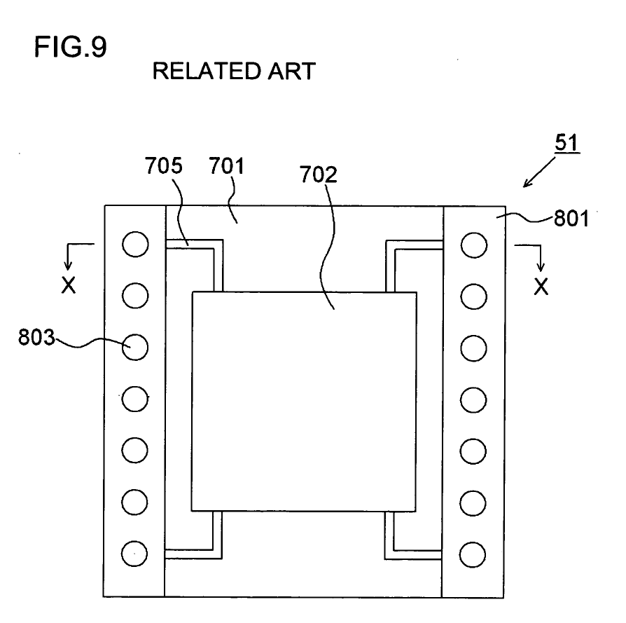

FIG. 10 shows a schematic cross sectional view of the semiconductor device along a line X-X of FIG. 9.

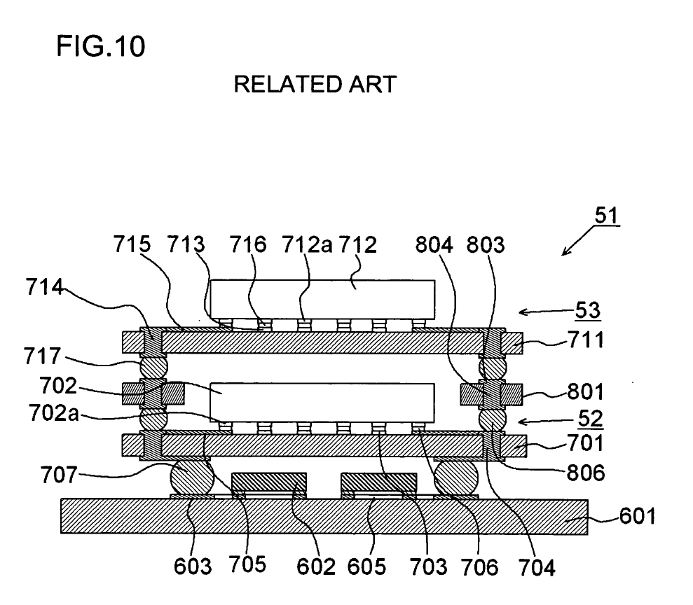

### DETAILED DESCRIPTION OF THE PREFERRED MODES

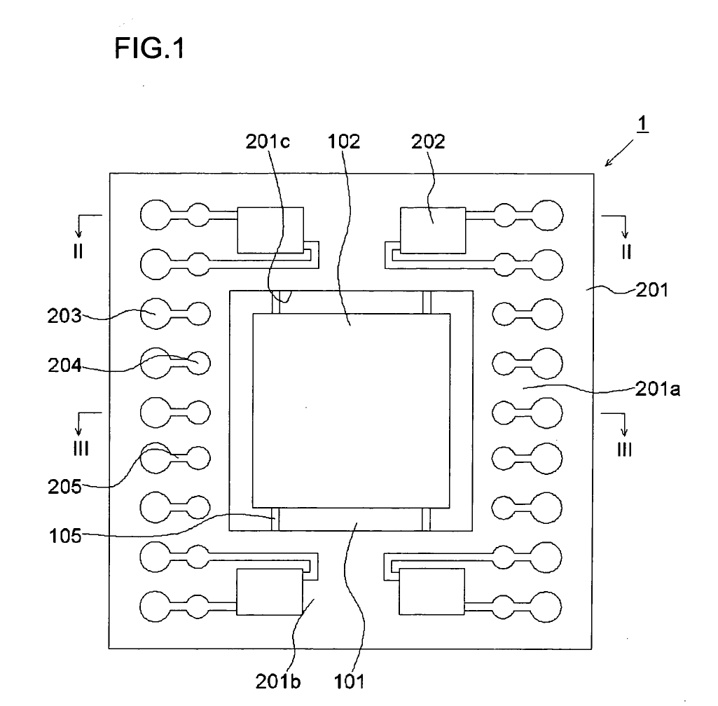

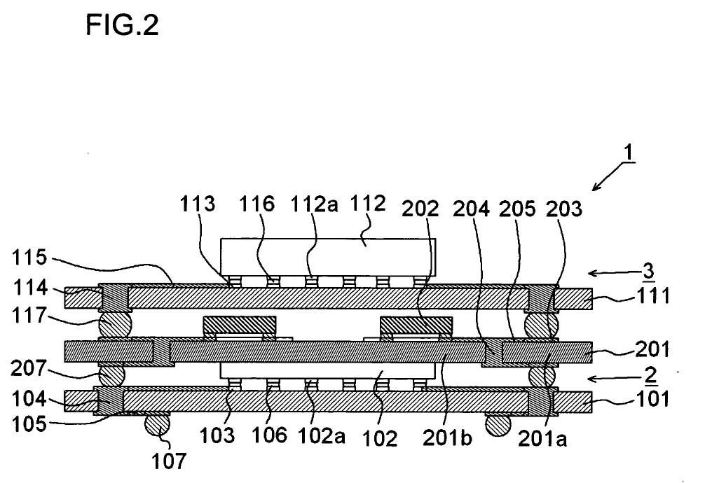

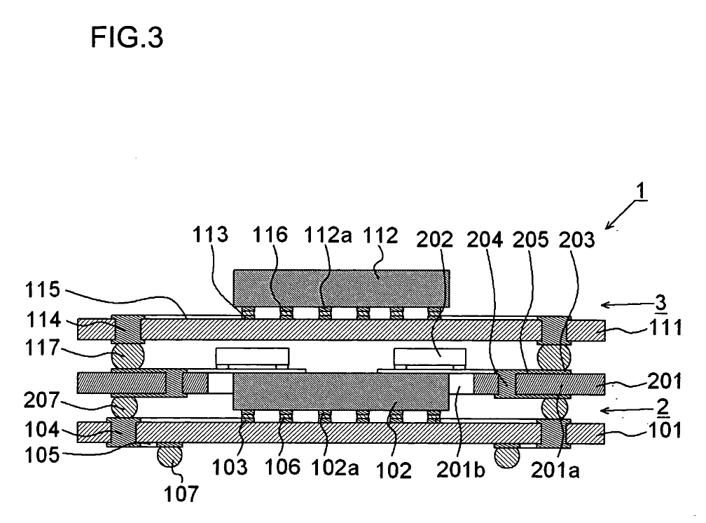

A description will be given relating to a semiconductor device according to a first exemplary embodiment. FIG. 1 shows a schematic top plan view viewed from above a spacer, in the semiconductor device according to the first exemplary embodiment. FIG. 2 shows a schematic cross sectional view of the semiconductor device along a line II-II of FIG. 1. FIG. 3 shows a schematic cross sectional view of the semiconductor device along a line III-III of FIG. 1. FIG. 1 does not show a second semiconductor package 3 that is above a spacer 201, as shown in FIG. 2 and FIG. 3.

The semiconductor device 1 has a plurality of semiconductor packages 2 and 3, and a first semiconductor package 2 and a second semiconductor package 3 are stacked. The respective semiconductor packages 2 and 3 have semiconductor elements 102 and 112, and package boards 101 and 111, and the semiconductor elements 102 and 112 are mounted on the package boards 101 and 111. Conductive vias 104 and 114 and pads 103 and 113 are formed on the package boards 101 and 111, and the conductive vias 104 and 114, and the semiconductor elements 102 and 112 are electrically connected through wiring layers 105 and 115.

The semiconductor device 1 additionally has a spacer 201. The spacer 201 is interposed between the first semiconductor package 2 and the second semiconductor package 3. The spacer 201 has a plurality of conductive vias 204 and pads 203 in order to electrically connect the first semiconductor package 2 and the second semiconductor package 3.

The pads 203 and the conductive vias 204 formed on an upper face and a lower face of the spacer 201 are electrically connected by a wiring layer 205. With regard to the first package board 101 and the spacer 201, the pads 103 of an upper face of the first semiconductor package board 101 and the pads 203 of a lower face of the spacer 201 are electrically connected by joining by a conductive body 207 such as a solder ball or the like. In a similar way, with regard to the second semiconductor package board 111 and the spacer 201, the pads 113 of a lower face of the second semiconductor package board 111 and the pads 203 of an upper face of the spacer 201 are electrically connected by joining by a conductive body 117 such as a solder ball or the like. In this way, the first semiconductor package 2 and the second semiconductor package 3 are electrically connected through the conductive vias 204 of the spacer 201.

The spacer 201 is a frame unit that has a through-hole section 201c that penetrates in a direction of stacking of the semiconductor packages 2 and 3. The first semiconductor element 102 that is disposed between the semiconductor packages 2 and 3 is inserted (disposed) in the through-hole section 201c. By accommodating a portion of the first semiconductor element 102 in the through-hole section 201c, it is possible to shorten the distance (height) between the first package board 101 and the spacer 201, and it is possible to make the diameter of the conductive body 207 for electrically connecting the first package board 101 and the spacer 201, smaller than that of a conductive body in the case where the first package board 101 and the spacer 201 are electrically connected without forming the through-hole section 201c. In this way, it is possible to prevent shorting between adjacent conductive bodies 207.

Furthermore, by the spacer 201 interposed between the first package board 101 and the second package board 111, it is possible to make diameters of the conductive bodies 207 and 117, such as solder balls or the like, used for electrically connecting the first package board 101 and the second package board 111, smaller than that of the conductive body in the case where the first package board 101 and the second package board 111 are electrically connected without the spacer 201 interposed therebetween. In this way, it is possible to prevent shorting between the conductive bodies to be formed between the first package board 101 and the second package board 111.

The spacer 201 additionally has at least one capacitor element 202. In the exemplary embodiment shown in FIG. 1 to FIG. 3, the spacer 201, in which a plurality of conductive vias 204 are formed, is formed in a frame shape (square shape) by electrical connection sections 201a arranged on either side of the first semiconductor element 102 (left and right sides in FIG. 1), and by a capacitor element mounting sections 201b arranged on either side of the first semiconductor element 102 (upper and lower sides in FIG. 1) that bridge between the two electrical connection sections 201a. The capacitor element(s) 202 is (are) mounted on the spacer 201, and is preferably mounted on the capacitor element mounting section 201b in which the conductive vias 204 are not formed. The capacitor element 202 is electrically connected, among the conductive vias 204, to a first conductive via that electrically connects the second semiconductor element 112 and a power supply, and a second conductive via that electrically connects the second semiconductor element 112 and ground, through the wiring layer 205.

By mounting the capacitor element 202 on the spacer 201, it is possible to reduce impedance between the power supply and GND viewed from the second semiconductor element 112, and thus it is possible to realize high speed operation of the second semiconductor element 112. That is, if the capacitor element 202 is integrated on an intermediate path of the second semiconductor element 112 and a mounting board (not illustrated in the drawings) on which the semiconductor packages 2 and 3 are mounted, with regard to impedance between the power supply and GND for high frequency viewed from the second semiconductor element 112, dominant are (an inductance component and a resistance component) between the power supply and GND that exist between the second semiconductor element 112 and the capacitor element 202, excepting parasitic components inside the capacitor element 202. Since the distance between the second semiconductor element 112 and the capacitor element 202 is shorter than a distance between the second semiconductor element 112 and the mounting board, the inductance component and the resistance component for high frequency viewed from the second semiconductor element 112 are relatively small compared to the case where the capacitor element 202 is not integrated. This means that impedance between the power supply and GND is decreased. If the impedance between the power supply and GND is decreased, since even when a similar current flows, voltage fluctuations are small, it is possible to suppress potential fluctuations between the power supply supplied to the second semiconductor element 112 and GND. In this way, an electrical characteristic of a circuit inside the second semiconductor element 112 becomes stable, and it is possible to achieve high speed operation.

In order to further decrease impedance between the power supply and GND, from the capacitor element 202 as far as the second semiconductor element 112, plural capacitor elements 202 are preferably mounted so that total capacitance of the capacitor elements 202 mounted on the spacer is the same. For example, in the exemplary embodiment shown in FIG. 1 to FIG. 3, at each and portion of each of the two capacitor element sections 201b, that is, close to the electrical connection sections 201a on each side, one capacitor element 202 is mounted, and a total of 4 capacitor elements are mounted on the spacer 201. A pattern of the wiring layer 205 that electrically connects the pads 203 and the capacitor elements 202 can be appropriately set by assignment of power supply/GND or a signal with regard to the spacer 201. Distance between the second package board 111 and the spacer 201, that is, size (diameter) of the conductive body 117 formed between the second package board 111 and the spacer 201, is set so that the capacitor elements 202 can be mounted. In the exemplary embodiment shown in FIG. 2 and FIG. 3, the size of the conductive body 117 formed between the second package board 111 and the spacer 201 is larger than that of the conductive body 207 between the first package 101 and the spacer 201.

In addition, by mounting the capacitor elements 202 on the spacer 201, it is possible to install the capacitor elements 202 in the semiconductor device 1 much cheaper than having the capacitor elements built-in in the semiconductor packages 2 and 3. Furthermore, since it is possible to manufacture the semiconductor packages 2 and 3 more cheaply than by having the capacitor elements built-in in the semiconductor packages, even when a semiconductor element that does not have a preferable electrical characteristic is mounted on the semiconductor packages 2 and 3, it is possible to reduce the cost incurred by rejecting semiconductor packages. Moreover, by containing the first semiconductor element 102 and mounting the capacitor elements on the spacer to make the conductive bodies 117 and 207 small, it is possible to effectively utilize the space between the semiconductor packages.

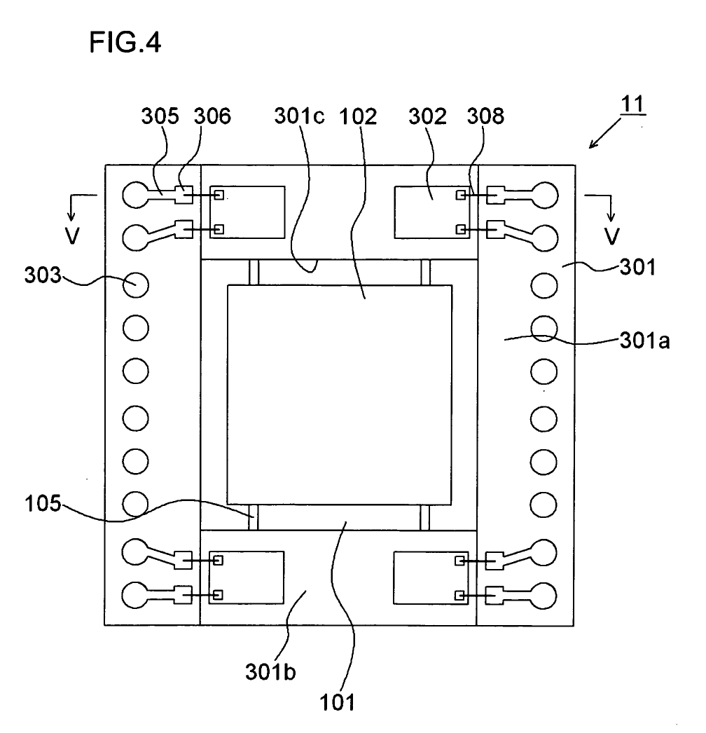

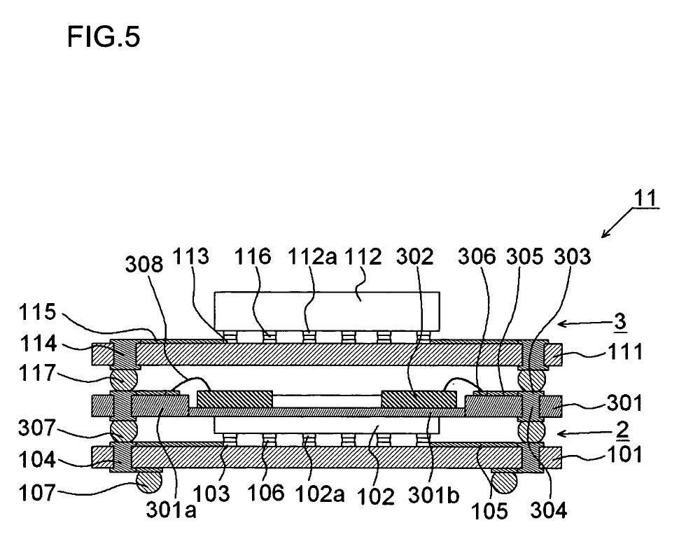

Next, a description will be given concerning a semiconductor device according to a second exemplary embodiment. FIG. 4 shows a schematic top plan view viewed from above a spacer, in the semiconductor device according to the second exemplary embodiment. FIG. 5 shows a schematic cross sectional view of the semiconductor device along a line V-V of FIG. 4. In FIG. 4, a second semiconductor package 3 above a spacer 301 shown in FIG. 5 is not illustrated.

In the first exemplary embodiment, the thickness of the spacer is uniform, that is, the thickness of the electrical connection sections and the capacitor element mounting sections is the same, but in the present exemplary embodiment the thickness of capacitor element mounting sections 301b in which capacitor elements 302 is mounted is formed to be thinner than electrical connection sections 301a. By making the capacitor element mounting sections 301b thin, it is possible to secure space in a direction of thickness for mounting the capacitor elements 302, and it is possible to make the size of conductive body 117 for electrically connecting a second semiconductor package 3 and the spacer 301 small (thinner) compared to the first exemplary embodiment. For example, it is possible to make the size of the conductive body 117 for electrically connecting the second semiconductor package 3 and the spacer 301, and conductive body 307 for electrically connecting the first semiconductor package 2 and the spacer 301, the same. In this way, it is possible to make stress acting on the conductive bodies 117 and 307 formed on upper and lower faces of the spacer, uniform, and it is possible to increase connection reliability in the conductive bodies 117 and 307. In addition, it is possible to make the height of the overall semiconductor device 11 lower. If it is possible to integrally form the electrical connection sections 301a and the capacitor element mounting sections 301b as the same member, formulation is also possible by bonding with adhesive, for example, using separate members.

Along with forming the capacitor element mounting sections 301b to be thin, in the first exemplary embodiment the capacitor elements were surface mounted, but in the present exemplary embodiment, the capacitor elements 302 can be wire-bonded. That is, conductive vias 304 and the capacitor elements 302 are electrically connected by the capacitor elements 302 and pads 306, which are electrically connected to the conductive vias 304 by a wiring layer 305, being electrically connected by bonding wire 308.

Furthermore, in the present exemplary embodiment, the pads 303 for mounting the conductive bodies 117 and 307 are directly formed on the conductive vias 304, not through the wiring layer.

In the second exemplary embodiment, the formulation other than the above description is similar to the first exemplary embodiment.

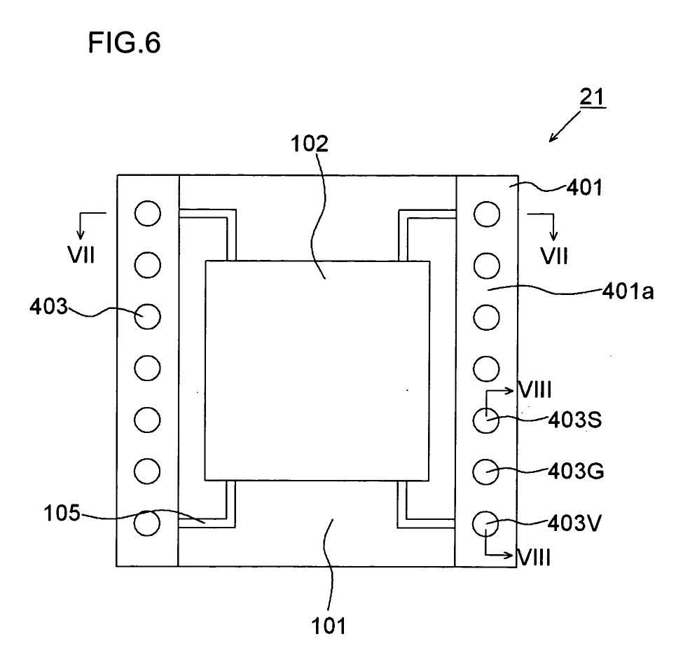

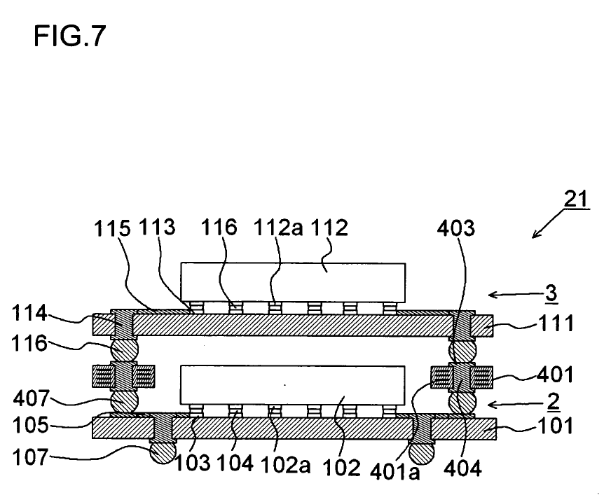

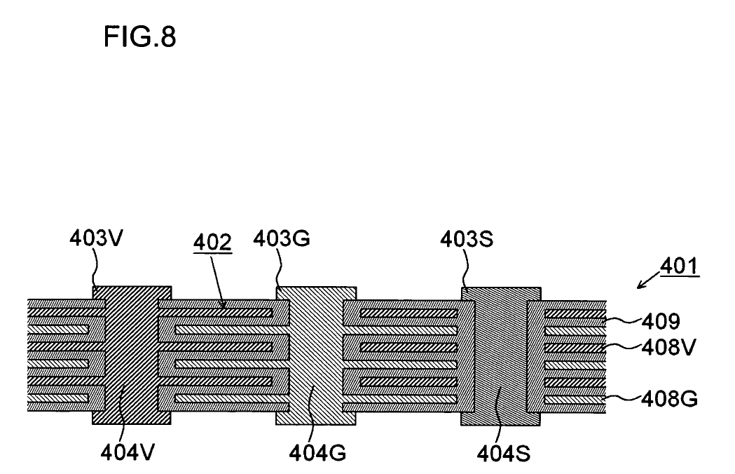

Next, a description will be given concerning a semiconductor device according to a third exemplary embodiment. FIG. 6 shows a schematic top plan view viewed from above a spacer, in the semiconductor device according to the third exemplary embodiment. FIG. 7 shows a schematic cross sectional view of the semiconductor device along a line VII-VII of FIG. 6. FIG. 8 shows a schematic cross sectional view of a spacer of the semiconductor device along a line VIII-VIII of FIG. 6. In FIG. 6, a second semiconductor package 3 above a spacer 401 shown in FIG. 7 is not illustrated.

In the first exemplary embodiment and the second exemplary embodiment, the spacer has electrical connection sections and capacitor element mounting sections, and a through-hole section is formed, but in the present exemplary embodiment, the spacer 401 does not have a capacitor element mounting section, and is formed with only two electrical connection sections 401a disposed on both sides of the first semiconductor element 102. In addition, in the first exemplary embodiment and the second exemplary embodiment, the capacitor elements are mounted above the spacer, but in the present exemplary embodiment, capacitor elements 402 are built-in in the spacer 401.

The spacer 401 has a plurality of conductive vias 404, a dielectric member 409, and conductor layers 408V and 408G, stacked in the dielectric member 409. First conductor layers 408V are conductor layers electrically connected to a first conductive via 404V electrically connected to a power supply, and second conductor layers 408G are conductor layers electrically connected to a second conductive via 404G electrically connected to GND. The first conductor layers 408V and the second conductor layers 408G are present in a plural number and alternately stacked with a dielectric member (or layer) 409, which is of a thin film form, being interposed therebetween, and a plurality of the capacitor elements 402 are formed. A third conductive via 404S, which is for a signal, is not electrically connected to the conductor layers 408V and 408G, and only passes through the spacer 401. Material of the dielectric member 409 may be any material as long as the capacitor elements 402 can be formed by being disposed between the first conductor layer 408V and the second conductor layer 408G.

In the present exemplary embodiment, the capacitor elements 402 are built-in in the spacer 401 by the dielectric member 409 and the conductor layers 408V and 408G being stacked, but the capacitor elements can also be built-in by a chip capacitor or the like being embedded in the spacer.

In the abovementioned exemplary embodiments, it is possible to use solder, conductive paste, or the like, as the conductive body (or member) that electrically connects the spacer and a package board. Furthermore, Anisotropic Conductive Film (ACF) or the like can be used as the conductive body.

In the abovementioned exemplary embodiments, modes are shown in which two semiconductor packages (semiconductor elements) are stacked, but clearly the number of layers in the present invention can also be three or more.

The semiconductor devices of the present invention have been described based on the abovementioned exemplary embodiments, but there is no limitation to the abovementioned exemplary embodiments, and clearly various types of modification, variation, and improvement are included, within the scope of the of the present invention, and based on fundamental technological concepts of the invention. In addition, various types of combinations, substitutions, and selections of various disclosed elements are possible within a scope of the claims of the present invention.

Further objects and expanded modes of the present invention will become apparent from the entire disclosed matter of the invention including the scope of the claims.

The semiconductor device of the present invention can be applied to various semiconductor devices, and, for example, can be applied to a semiconductor memory device. Furthermore, in the abovementioned exemplary embodiments, a description was given of mounting and building-in of capacitor elements, but a passive element other than the capacitor element can also be employed in the semiconductor device of the present invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
plural semiconductor packages stacked with a spacer interposed therebetween,
said semiconductor package comprising a semiconductor element mounted on a package board, wherein
said spacer has a plurality of conductive vias and at least one capacitor element;
said semiconductor packages are electrically connected to one another by said conductive vias; and
said capacitor element is electrically connected, among said conductive vias, to a first conductive via that electrically connects said semiconductor element and a power supply, and to a second conductive via that electrically connects said semiconductor element and ground.

2. The semiconductor device according to claim 1, wherein
said spacer comprises a frame unit that has a through-hole section penetrating in a direction of stacking of said semiconductor packages; and
said semiconductor element, which is disposed between two of said semiconductor packages adjacently stacked, is inserted in said through-hole section of said spacer that is arranged between said two semiconductor packages.

3. The semiconductor device according to claim 1, wherein
said capacitor element is mounted on said spacer; and
said capacitor element, and said first conductive via and said second conductive via are electrically connected by a wiring layer formed on said spacer.

4. The semiconductor device according to claim 1, wherein
said spacer has an electrical connection section in which said conductive vias are formed, and a capacitor element mounting section in which said capacitor element is mounted; and
said capacitor element mounting section has a thickness in a direction of stacking of said semiconductor packages thinner than that of said electrical connection section.

5. The semiconductor device according to claim 4, wherein said capacitor element is electrically connected to said conductive via by wire bonding.

6. The semiconductor device according to claim 1, wherein said capacitor element is built in said spacer.

7. The semiconductor device according to claim 6, wherein
said spacer additionally has a dielectric and a plurality of conductor layers stacked in said dielectric;
said plurality of conductor layers have a first conductor layer electrically connected to said first conductive via, and a second conductor layer electrically connected to said second conductive via; and
said capacitor element is formed by said first conductor layer and said second conductor layer being alternately stacked with said dielectric being interposed therebetween.

8. The semiconductor device according to claim 7, wherein said first conductor layer and said second conductor layer are not electrically connected, among said plurality of conductive vias, to a third conductive via dedicated for a signal.
